(19) United States
(12) Patent Application Publication
(10) Pub. No.: US 2001/0019807 A1
(43) Pub. Date: Sep. 6, 2001

(54) Deposition mask and manufacturing method thereof, and electroluminescence display device and manufacturing method thereof

(76) Inventors: Tsutomu Yamada, Motosu-gun (JP); Yoshihiro Morimoto, Inazawa-city (JP); Kiyoshi Yoneda, Motosu-gun (JP)

Correspondence Address: Michael A. Cantor, Esq., CANTOR COLBURN LLP, 55 Griffin Road South, Bloomfield, CT, 06002, US

(21) Appl. No.: 09/748,470

(22) Filed: Dec. 26, 2000

(30) Foreign Application Priority Data
Dec. 24, 1999 (JP) 11-367123

(51) Int. Cl. G03C 5/16; B05D 1/32; B05D 3/00; B05D 5/00; B05D 5/06

(52) U.S. Cl. 430/139; 427/272; 427/162

(57) ABSTRACT

A single crystal or polycrystalline silicon substrate (100) is formed as a semiconductor substrate. Using a resist (103), an SiO₂ film (101) is formed as a first coating on at least part of the outer periphery of the substrate (100). While using this SiO₂ film (101) as a mask, the substrate (100) is etched from the first surface side using KOH or the like. The thickness of the substrate is thus decreased to thereby form an opening forming region M, whereas a region of the substrate covered with the first coating is not etched to thereby form a thick portion 140. Then, on a second surface of the substrate (100), a second coating is formed by applying a resist (104) at a region of the substrate other than where opening are to be formed in the region M. The substrate is then etched using the second coating as a mask to form holes, as openings (110), at regions not covered by the second coating. By using the thus obtained deposition mask (100) as a mask for evaporation, a material can be deposited to a desired location with high accuracy.

### BACKGROUND OF THE INVENTION

1. Field of the Invention

The present invention relates to a deposition mask (evaporation mask) used when evaporating an emissive layer material onto an electroluminescence (referred to hereinafter as “EL”) element, and to a method for manufacturing such a deposition mask. The present invention also relates to an EL display device manufactured using such a deposition mask, and to a method for manufacturing such an EL display device.

2. Description of the Related Art

In recent years, EL display devices comprising EL elements have gained attention as potential replacements for CRTs and LCDs.

Research has been directed to the development of EL display devices using thin film transistors (referred to hereinafter as “TFT”) as switching elements for driving the EL elements.

FIG. 1 is a plan view showing an area around one display pixel of an organic EL display device according to a related art. FIG. 2A shows a cross-sectional view taken along line D-D of FIG. 1, while FIG. 2B shows a cross-sectional view taken along line E-E of FIG. 1.

As shown in FIG. 1, surrounding the region in which each display pixel is formed are gate lines 51 and drain lines 52. A first TFT 30 serving as a switching element is disposed near an intersection of those lines. The source 11s of the TFT 30 simultaneously functions as a capacitor electrode 55 such that, together with the opposing storage capacitor electrode line 54 described later, it forms a capacitor. The source 11s is connected to a gate 43 of a second TFT 40 for driving the EL element. The source 41s of the second TFT 40 is connected to the anode 61 of the organic EL element 60. The drain 41d is connected to a power source line 53 which supplies current to the organic EL element 60.

Near the TFTs, a storage capacitor electrode line 54 is disposed in parallel with a gate line 51. The storage capacitor electrode line 54 is made of a material such as chromium. The storage capacitor electrode line 54 opposes to the capacitor electrode 55 via a gate insulating film 12 and together stores charges, forming a capacitor. The capacitor electrode 55 is connected to the source 11s of the TFT 30. This storage capacitor is provided for retaining voltage applied to the gate 43 of the second TFT 40.

As shown in FIGS. 2A and 2B, the organic EL display device is formed by sequentially laminating the TFTs and the organic EL element on a substrate 10 made of a material such as glass or synthetic resin, or on a conductive or semiconductor substrate.

The first TFT 30, or the switching TFT, will now be explained.

As shown in FIG. 2A, on an insulator substrate 10 made of quartz glass, non-alkali glass, or a similar material, an amorphous silicon film (a-Si film) is formed using a CVD or other method. The a-Si film is irradiated with a laser beam to be polycrystallized, forming a polycrystalline silicon film (p-Si film) 11 which serves as an active layer. A gate insulating film 12 is formed over the p-Si film 11. Further on top are disposed gate lines 51 which are made of a refractory metal such as chromium (Cr) or molybdenum (Mo) and which also serve as gate electrodes 13. An interlayer insulating film 14 is then provided over the entire substrate surface over the gate lines 51. Drain signal lines 52 composed of aluminum (Al), which also serve as drain electrodes 15, are disposed on the interlayer insulating film 14.

The interlayer insulating film 14 formed by sequential lamination of a SiO₂ film, a SiN film, and a SiO₂ film is provided on the entire surface over the gate insulating film 12, the gate electrodes 13, power source lines 53, and storage capacitor electrode lines 54. A contact hole is formed through the gate insulating film 12 and the interlayer insulating film 14 in a position corresponding to a drain lid. This contact hole is filled with a metal such as Al, forming a drain electrode 15. Further on top, a planarizing insulating film 16 made of an organic resin or a similar material is formed covering the entire substrate surface for planarization.

The second TFT 40, or the TFT for driving the organic EL element, will next be described.

As shown in FIG. 2B, sequentially formed on the insulator substrate 10 made of a material such as quartz glass or non-alkali glass are an active layer 41 composed of a p-Si film disposed at the same time with the active layer of the first TFT 30, a gate insulating film 12, and gate electrodes 43 made of a refractory metal such as Cr or Mo. The active layer 41 includes channels 41c, and, on respective sides of these channels 41c, a source 41s and a drain 41d. The above-described interlayer insulating film 14 is provided on the entire surface over the active layer 41, the gate insulating film 12 and gate electrodes 43. A contact hole is formed through the gate insulating film 12 and the interlayer insulating film 14 in a position corresponding to the drain 41d. This contact hole is filled with a metal such as Al, forming a power source line 53 connected to a power source. Further, a planarizing insulating film 16 made of an organic resin or a similar material may be formed over the entire surface for planarization. A contact hole is then formed through the planarizing insulating film 16, the interlayer insulating film 14, and the gate insulating film 12 in a position corresponding to the source 41s. A transparent electrode made of ITO (indium tin oxide) that contacts the source 41s through this contact hole, namely, the anode 61 of an organic EL element, is formed on the planarizing insulating film 16.

The organic EL element 60 is formed by first laminating the anode 61 constituted by a transparent electrode made of ITO or a similar material, over which the emissive element layer 66 is then superimposed. The emissive element layer 66 comprises a first hole-transport layer 62 composed of a material such as MTDATA (4,4′,4″-tris(3-methylphenylphenylamino)triphenylamine), a second hole-transport layer 63 composed of a material such as TPD (N,N′-diphenyl-N,N′-di(3-methylphenyl)-1,1′-biphenyl-4,4′-diamine), an emissive layer 64 composed of, for example, Bebq₂ (bis(10-hydroxybenzo[h]quinolinato)beryllium) including quinacridone derivatives, and an electron transport layer 65 composed of Bebq₂ or a similar material. Subsequently, a cathode 67, which may be composed of a magnesium-indium alloy, is formed. All of the above-noted layers of the organic EL element 60 are laminated in the described order. An insulating film 68 is provided to prevent short-circuiting between an edge of the anode 61 and the cathode 67. The organic EL element 60 as described above constitutes a display pixel.

In the organic EL element, holes injected from the anode and electrons injected from the cathode recombine in the emissive layer. As a result, organic molecules constituting the emissive layer are excited, generating excitons. Through the process in which these excitons undergo radiation until deactivation, light is emitted from the emissive layer. This light radiates outward through the transparent anode via the transparent insulator substrate, resulting in light emission.

As described above, an organic material of the emissive layer in each display pixel is provided on each anode 61. The organic material may be formed by an evaporation method, for example.

FIG. 3 diagrammatically shows an arrangement of display pixels 1R, 1G, and 1B for respective colors.

As shown in the figure, the display pixels 1R, 1G, 1B for the respective colors are formed in regions on an insulator substrate 10 surrounded by gate lines 51 and drain lines 52 and power source lines 53, and are repeatedly arranged by rows in the order of R, G, and B. The display pixels 1R, 1G, 1B include an anode 61R corresponding to red, an anode 61G corresponding to green, and an anode 61B corresponding to blue, respectively. Each anode 61R, 61G, 61B is formed in an island pattern. On these anodes, the organic emissive materials of the emissive layer are formed to enable emission of light having different colors.

FIG. 4 is a cross-sectional view illustrating an evaporation process of an organic material constituting an emissive layer. This figure shows, as an example, evaporation of a red organic emissive material. Components that are identical to those in FIGS. 2A and 2B are labeled with the same reference numerals.

In FIG. 4, an organic material for emitting red light is formed on a red color display electrode (anode) 61R connected to a second TFT 40 provided on a glass substrate 10.

When forming the organic material, a metal mask made of a metal such as nickel (Ni), which has an opening in a position corresponding to the red anode, is placed in contact with each anode. While in this state, a evaporating material, i.e., the red organic material, from a evaporating material source, i.e., the organic material placed in a holder, is evaporated onto a region including the anode 61R on the glass substrate 10.

FIG. 5 is a cross-sectional view illustrating how a metal mask is mounted for performing evaporation of an organic material for each color onto a glass substrate on which TFTs and anodes are formed.

As shown in FIG. 5, a metal mask 95 having openings 110 in positions corresponding to anodes is installed in an evaporation mask holder 125 including a mask fixture 126 in the surrounding periphery portion, and is arranged on a glass substrate 10 having components formed thereon up to the anodes as shown in FIG. 4. To prevent the mask from deflecting, the metal mask 95 is held in tension by the four sides of the evaporation mask holder 125 while the mask is being arranged on the substrate 10. In addition, a magnet 120 is placed on a side of the glass substrate 10 opposite from the side on which the metal mask 95 is arranged. Furthermore, the mask fixing jig 125 disposed in a region surrounding the substrate has a groove formed therein, and the periphery portion of the mask 95 is placed along the position of the groove. From a side of the mask 95 opposite from the side contacting the jig 125, the fixture 126 is fitted into the groove of the jig 125 while the mask is sandwiched in between. By employing the jig 125 and the fixture 126 in this manner, warping of the metal mask 95 is prevented.

However, even when the metal mask 95 is held on its periphery portions and fixed using a magnet from the opposite side as described above, deflection results. From the center towards the periphery portion of the metal mask 95, the openings 110 of the mask 95 become misaligned with respect to the positions of the anodes 61 onto which the organic material is to be evaporated. The emissive material is therefore evaporated at positions shifted from the positions at which evaporation should actually be performed. This causes the drawback that predetermined colors cannot appropriately be emitted by the EL display device.

When forming the openings 110 of the metal mask 95, photolithography can be used to form openings in the metal mask material, which may be Ni. However, when the thickness of the metal mask 95 is relatively large, for example, approximately 100 μm, an error of approximately ±10 μm is generated in the size of the openings, resulting in a poor machining accuracy of the openings 110.

The metal mask 95 may be formed using a mask electroforming technique. According to this technique, a metal piece on which electrodeposition is performed to form the metal mask 95 is placed in an electrolyte containing Ni. When the electrodeposited metal piece is removed from the electrolyte after Ni is electrodeposited thereon, the Ni surface disadvantageously becomes greatly warped due to volumetric shrinkage. Similar warping of the Ni surface also results in a metal mask 95 formed using the above-noted photolithographic technique.

Further, when the electrodeposition technique is employed, projections are formed in the Ni surface. The projections may contact the glass substrate and scar the substrate surface.

Another existing drawback of a conventional deposition mask is that it may break during an attempt to remove the organic material which became attached to the mask through its repeated use in depositions.

### SUMMARY OF THE INVENTION

The present invention was formed in light of the above disadvantages. The purpose of the present invention is to obtain a highly precise deposition mask for evaporation, and to provide an EL display device wherein organic materials are very accurately formed in predetermined positions using such a deposition mask.

To achieve the above purposes, the present invention provides a deposition mask for placing between a depositing material and a medium on which deposition is performed, including a pattern for allowing the depositing material to be selectively attached to a desired position on the medium, wherein the mask is composed of a semiconductor substrate.

It is another aspect of the present invention to provide a deposition mask for placing between a depositing material and a medium on which deposition is performed, comprising a semiconductor substrate including an opening forming region having a reduced thickness provided with at least one opening for allowing the depositing material to be selectively attached to a desired position on the medium, and a thick portion formed in at least one portion of an outer periphery region of the mask.

A further aspect of the present invention is a method for manufacturing a deposition mask as described above, this method comprising the steps of forming a first coating covering a region in which said thick portion of said semiconductor substrate is to be formed, using the first coating as an etching mask to etch the semiconductor substrate so as to reduce thickness of the semiconductor substrate and thereby form the opening forming region, forming a second coating in areas other than a predetermined position within the opening forming region, and using the second coating as an etching mask to etch the semiconductor substrate so as to form said at least one opening in the substrate.

According to another aspect of the present invention, in the deposition mask manufacturing method described above, the first coating is formed on a first side of the semiconductor substrate, and the opening forming region is formed by etching the first side of the semiconductor substrate to reduce thickness of the substrate. Furthermore, the second coating is formed on a second side of the semiconductor substrate, and said at least one opening is formed by etching from the second side until penetrating through the semiconductor substrate.

According to a further aspect of the present invention, the semiconductor substrate constituting the above deposition mask is composed of silicon. This silicon may be single crystalline or polycrystalline silicon.

By forming a deposition mask using a semiconductor substrate, such as the above-noted silicon material, according to the present invention as described above, a highly accurate deposition mask in which no deflection occurs can be readily formed. When using such a deposition mask to, for example, evaporate an organic material for forming an emissive layer of an EL display element, deposition the organic material onto an adjacent anode of a different color display pixel can be prevented. This eliminates color blurring and makes possible vivid display of a desired color.

According to the present invention, the deposition mask is not formed by placing a metal piece for electrodeposition into an electrolyte, as in the case of a conventional metal mask. It is therefore possible to eliminate the problem of deflecting metal surface due to volumetric shrinkage occurring when the metal piece is removed from the electrolyte after electrodeposition.

Furthermore, the problem of scarring of the glass substrate surface by the projections resulting in the Ni surface when using the electrodeposition technique can be overcome.

Still further, the thick portion included in the outer periphery region of the deposition mask of the present invention prevents breakage of the deposition mask when mounting the mask on a device onto which deposition is performed or when removing an organic material which became attached to the mask through its repeated use in depositions.

At the same time, because the opening forming region is sufficiently thin, the step of etching through the semiconductor substrate to form an opening can be completed in a short time, and the opening can be shaped with a high accuracy. Moreover, by making the opening forming region thin, the material supplied from the depositing material source can reach the medium via a short hole (i.e., the opening), allowing the medium to be provided with the depositing material in an efficient manner and with a high positional accuracy.

Another aspect of the present invention provides a method for manufacturing an electroluminescence display device composed by arranging a plurality of display pixels, each display pixel having an electroluminescence element including at least an emissive layer between first and second electrodes, the method comprising the steps of arranging the above-described deposition mask on a medium having the first electrode formed thereon, and attaching an emissive material from an emissive material source via the opening of the deposition mask to a corresponding display pixel region of the medium, thereby forming an emissive layer for each pixel.

According to a further aspect of the present invention, in the above method for manufacturing an electroluminescence display device, each element includes between the first and second electrodes at least an emissive layer containing an organic material, and the organic material supplied from the emissive material source is attached via the opening of the deposition mask to a corresponding pixel.

According to a still further aspect of the present invention, in the above method for manufacturing an electroluminescence display device, each element is formed by including between the first and second electrodes at least an emissive layer containing an organic material corresponding to an emitted color. The deposition mask having the opening formed only in a region corresponding to a pixel for a predetermined color is used to attach the organic material supplied from the emissive material source to a corresponding pixel region.

According to the present invention, a highly precise deposition mask can be obtained. By using such a mask to attach an organic or other material to an adherend, a material for a predetermined color can accurately be deposited at a predetermined position, realizing an EL display device which achieves vivid color indication.

The above electroluminescence display device according to the present invention may be an organic EL display device. When depositing each of different organic emissive materials by evaporation onto pixels designated for light emission of a predetermined color, use of the above-described mask of the present invention as an evaporation mask facilitates accurate formation of an organic emissive layer in each pixel.

### BRIEF DESCRIPTION OF THE DRAWINGS

FIG. 1 is a diagram for explaining a plan configuration of a region around one display pixel of an organic EL display device.

FIG. 2A is a diagram showing a schematic cross-sectional configuration along line D-D of FIG. 1.

FIG. 2B is a diagram showing a schematic cross-sectional configuration along line E-E of FIG. 1.

FIG. 3 is a diagram conceptually illustrating a layout of display pixels correlated to respective colors of R, G, and B within a panel of an organic EL display device.

FIG. 4 is a diagram for explaining an evaporation process of an organic material constituting an emissive layer of the organic EL display device.

FIG. 5 is a diagram for explaining a method for using a conventional metal mask employed for evaporation of an organic material.

FIGS. 6A and 6B are diagrams illustrating the configuration and the state of use of a deposition mask according to a first embodiment of the present invention.

FIG. 7 is a diagram showing a silicon substrate used for the deposition mask according to the present invention.

FIGS. 8A, 8B, 8C, 8D, and 8E are cross-sectional views explaining a process for manufacturing the deposition mask according to the embodiment of the present invention.

FIGS. 9A, 9B, and 9C are diagrams illustrating the configuration and the state of use of a deposition mask according to a second embodiment of the present invention.

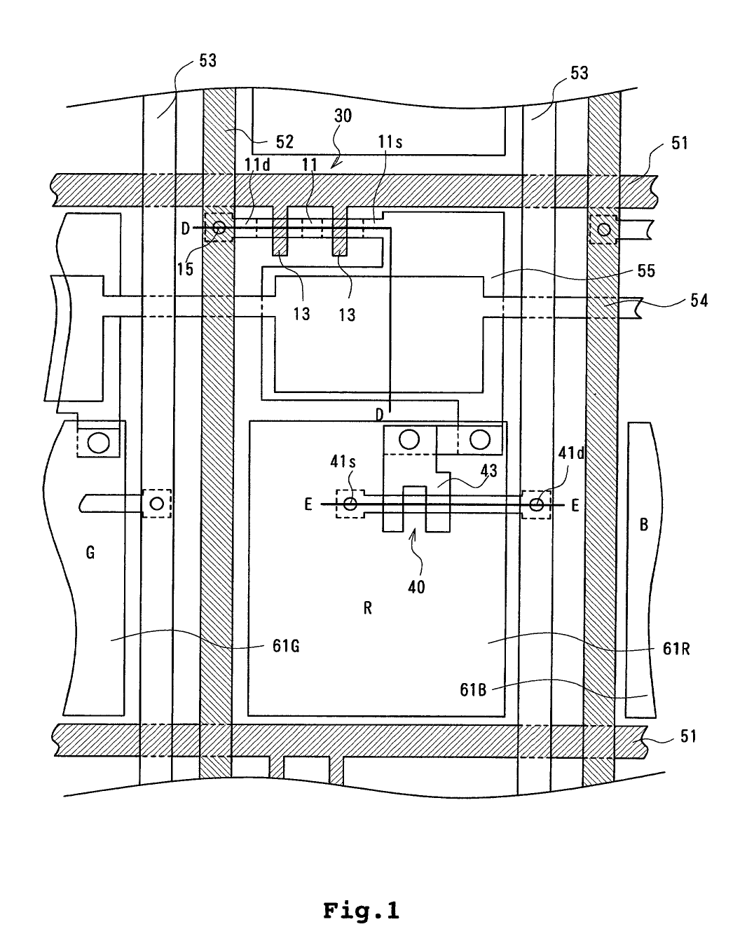

### DETAILED DESCRIPTION OF THE PREFERRED EMBODIMENTS

Preferred embodiments of the present invention will be described in further detail with reference to the accompanying drawings.

A mask used for deposition of a material (hereinafter referred to as a deposition mask) and an organic EL display apparatus manufactured using the deposition mask for evaporation will be described.

First Embodiment

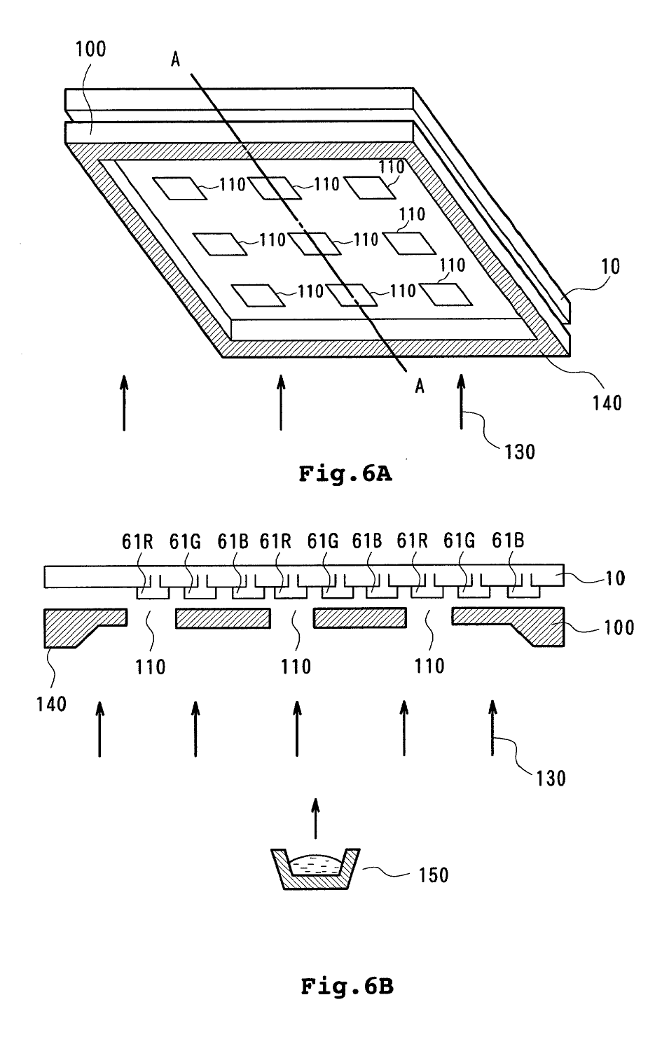

FIGS. 6A and 6B show a state where an organic material, which is a material to be deposited, is to be evaporated using a deposition mask of the present invention. More specifically, FIG. 6A is a perspective view illustrating a deposition mask being in contact with a glass substrate on which an organic material is to be evaporated, and FIG. 6B is a cross section taken along line A-A of FIG. 6A.

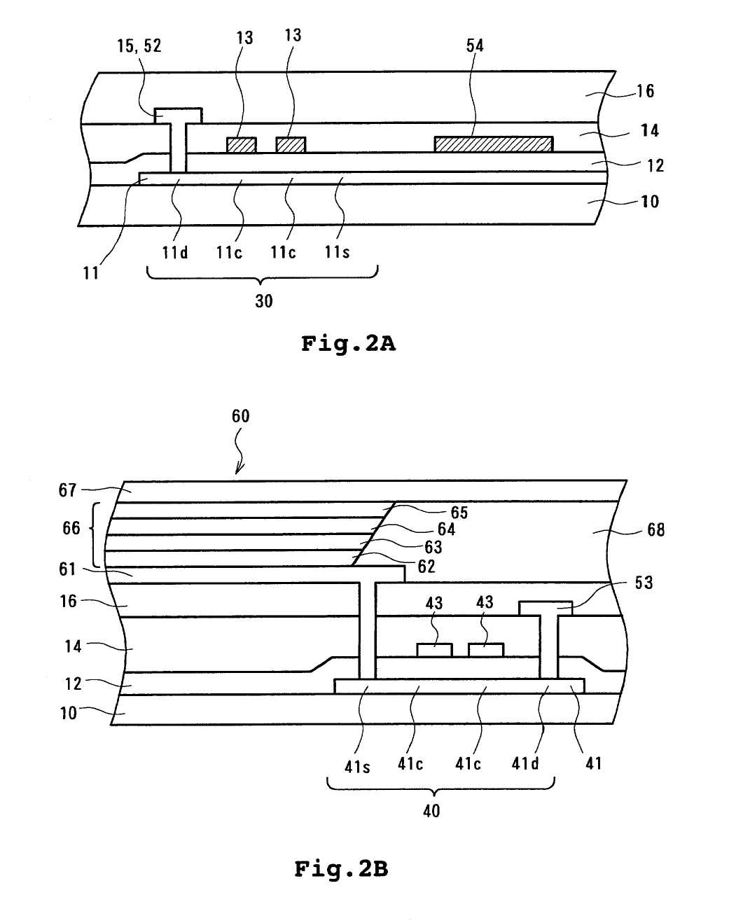

In actuality, although only the glass substrate 10 is shown in FIG. 6A, various films constituting the TFT 40 for driving an organic EL element and the anode 61 are first formed on the glass substrate 10 in the order shown in FIG. 2B. Similarly, although only the anodes 61R, 61G, 61B are shown on the glass substrate 10 in FIG. 6B, the TFT 40 and the anodes 61R, 61G, and 61B are actually disposed in that order on the glass substrate 10, and the glass substrate 10 functions as a base medium on which a material is to be deposited. Further, although not shown in FIGS. 6A and 6B, the structure of the TFT is the same as that in FIGS. 2A and 2B.

Referring to FIGS. 6A and 6B, over the above-described glass substrate 10, a deposition mask 100 composed of single crystal silicon (Si) and having a thick portion 140 along the outer periphery, which is thicker than an opening forming region at the center of the mask, is disposed so that the substrate 10 and the mask 100 contact with each other. An organic material is then evaporated from a holder 150 holding a material source containing an organic material and disposed at the lower side of the mask 100 in FIG. 6B. For convenience of explanation, the deposition mask 100 and the glass substrate 10 are not shown in contact with each other in FIGS. 6A and 6B.

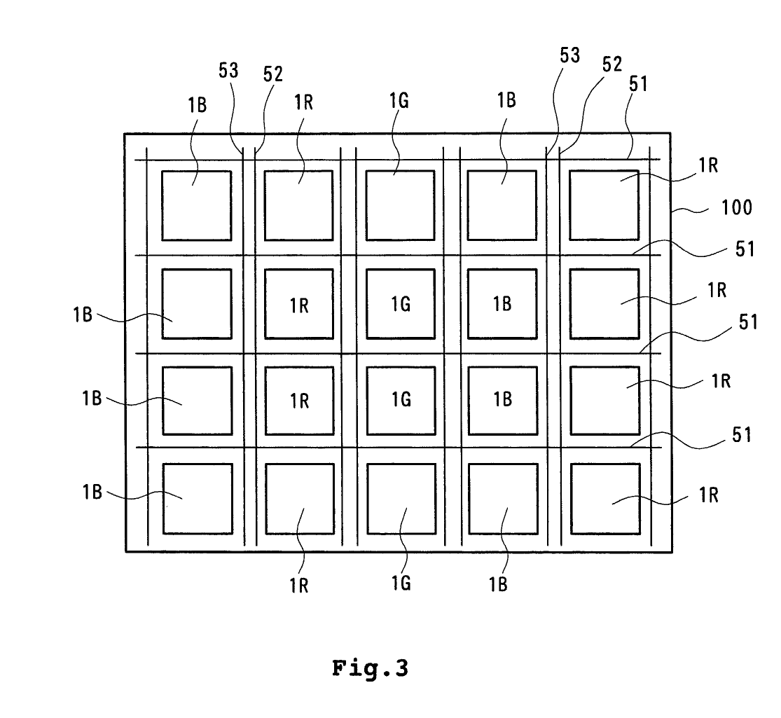

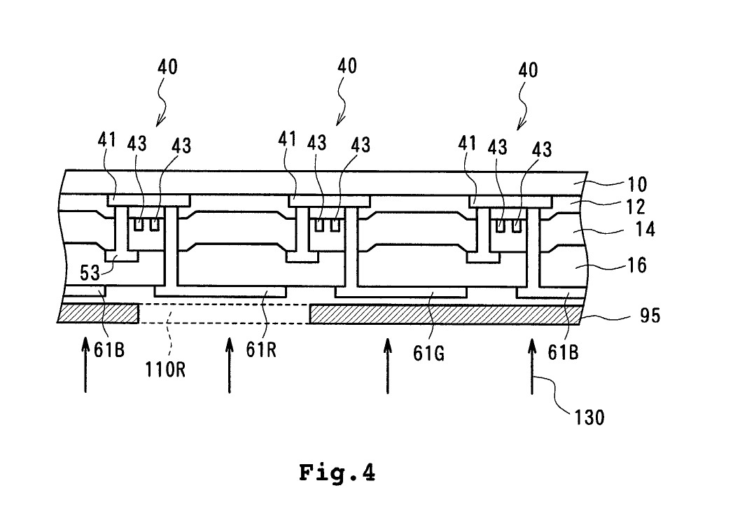

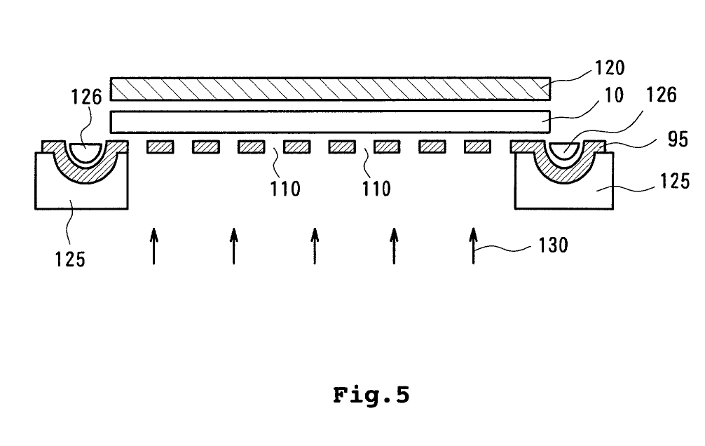

The deposition mask 100 has openings 110. In the example shown in FIGS. 6A and 6B, the openings 110 corresponding to all of the pixels for R, G, B are not formed in a single mask 100, but they are formed at positions corresponding to pixels for any one color of R, G, and B. More specifically, the mask 100 shown in FIGS. 6A and 6B is an example of a mask for R pixels in a case where a set of display pixels 1R, 1G, 1B are repeatedly provided in that order in the horizontal direction from the left side of the figure as shown in FIG. 3.

In FIGS. 6A and 6B, the TFT and the anode are preformed on the substrate, when, similar to the emissive layer, an organic layer in the organic EL element other than the emissive layer, such as a hole transport layer, is also composed of materials different for each color R, G, B. However, when an organic layer such as the hole transport layer is formed by the identical material for all the pixels, the organic hole transport layer has been preformed by evaporation on the anode disposed on the substrate 10 in FIGS. 6A and 6B.

As shown in FIG. 6B, when the anodes 61R, 61G, 61B formed on the display pixels 1R, 1G, 1B are repeatedly disposed in this order, the openings 110 of the mask 100 for R pixels are formed at positions corresponding to the anodes 61R formed on the display pixels 1R for red color. Using this mask 100, an organic material of red color is evaporated onto the anode 61R of the red display pixel 1R.

A method of making the deposition mask 100 will be now described.

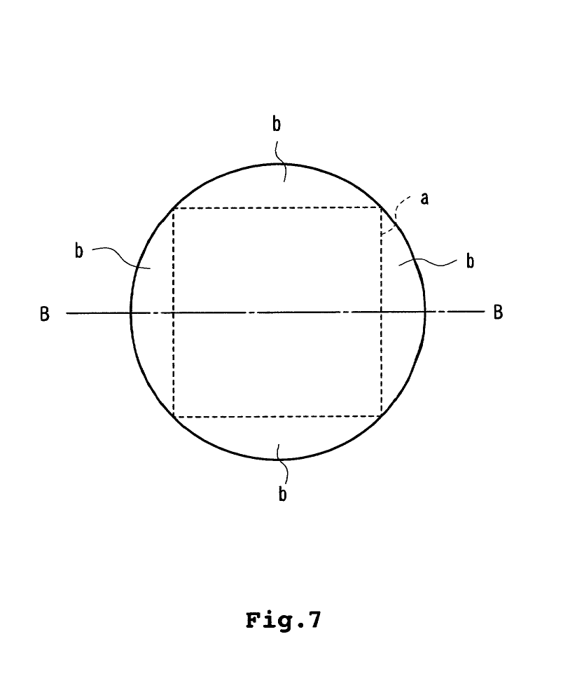

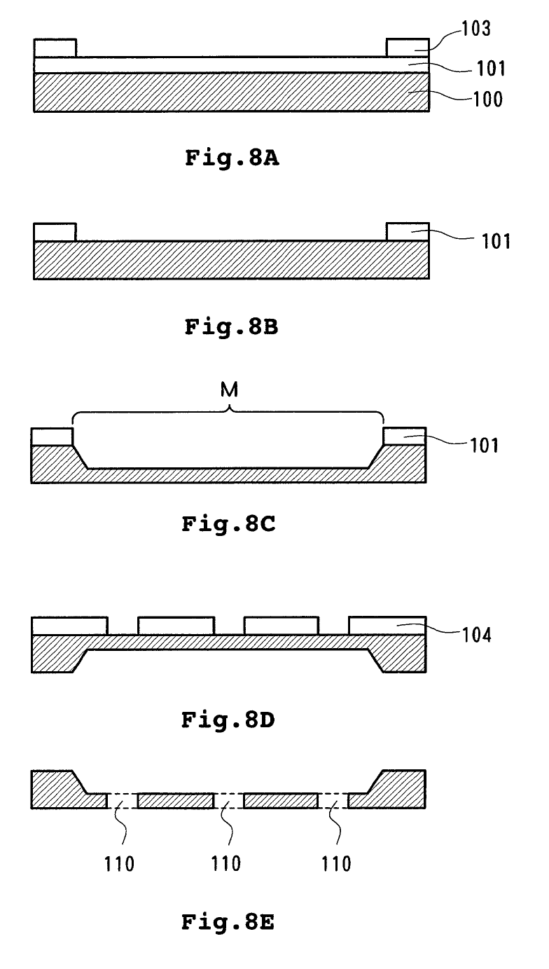

FIG. 7 shows a single crystal silicon wafer to be used as a material of a deposition mask according to the present invention. FIGS. 8A through 8E are cross sections taken along line B-B in FIG. 7 for illustrating a method of making the deposition mask.

Process Step 1 (FIG. 8A):

On a single crystal Si substrate 100 as shown in FIG. 7, an insulating film 101 such as an SiO₂ film is formed using a CVD method or the like. At this time, the thickness of the single crystal Si substrate is approximately 0.5 mm. Further, on the insulating film 101, a resist 103 is provided and is then removed such that a frame is left along the periphery of the Si substrate 100 such that the center portion of the Si substrate 100 has an opening. The width of the frame-shaped resist 103 left on the insulating film 101 is chosen to be sufficient for maintaining the rigidity of the mask, and may be, for example, approximately 1-2 mm from the outer edge of the mask, though it depends on the size of the resultant mask 100, namely the size of the display panel.

Process Step 2 (FIG. 8B):

A region of the SiO₂ film 101 which is not covered with the resist 103 is then removed by a dry etching method.

Process Step 3 (FIG. 8C):

After removing the resist 103, a potassium hydroxide (KOH) solution is used as an etchant to etch the Si substrate 100 using the SiO₂ film 101 as a mask. In this case, only the SiO₂ film 101 constitutes a first coating for the mask substrate. However, when the resist 103 is not removed and is used as a mask along with the SiO₂ film 101, both of the resist 103 and the SiO₂ film 101 serve as the first coating for the mask substrate.

The Si substrate which is used to form the deposition mask preferably has (100) surface orientation. This is because the etchant KOH etches only a surface with (100) orientation of the Si substrate, and can effectively etch a region for forming a mask in the substrate to uniformly decrease the thickness of that region. For example, the etching rate of 2 μm per minute can be achieved when etching is performed using the above-mentioned KOH.

When the foregoing etching process is completed, the thickness of the mask Si substrate 100 in the peripheral region where the first coating is formed is substantially maintained to a thickness prior to the etching. The thickness of the mask substrate in a center region where the first coating is not formed, namely an opening forming region M, is 100 μm or less, preferably 50 μm or less, and more preferably 30 μm or less. As the thickness of the region M decreases, the opening 110 of the mask, namely the opening used for deposition, coincides more precisely with the area where an organic material is actually deposited by evaporation through the opening, when the mask is disposed over the glass substrate 10 for used in evaporation. When the mask is too thin, however, there is a danger of damaging the mask. Accordingly, for the mask 100 to secure the minimum rigidity, the lower limit of the thickness of the mask in the region M is approximately 10 μm.

The thickness of the opening forming region M can be controlled by choice of etchant, temperature, and etching time.

Process Step 4 (FIG. 8D):

After the region M with thickness decreased by etching as described above is formed, a resist 104 is applied over the entire region of the rear surface of the Si substrate 100 and is then patterned such that it has openings at positions corresponding to openings 110 which will be formed in the Si substrate 100. The size of the opening formed in the resist 104 may be determined such that the opening 110 of the deposition mask, which will be formed using the resist 104 as an etching mask as will be described later, is larger than the anode, and such that the organic material to be evaporated using the deposition mask 100 can be evaporated so as to cover the anode and the periphery thereof. The resist 104 having such openings constitutes a second coating for the deposition mask 100.

Process Step 5 (FIG. 8E):

Using the above-mentioned resist pattern 104 as a mask, dry etching is performed by applying an etching gas SF₆ from above the Si substrate 100 in FIG. 8D to etch the Si substrate 100 and form the deposition openings 110 in the substrate 100. Then, the resist pattern 104 is removed.

Referring back to FIG. 7, the single crystal Si wafer having a circular shape is then cut into a shape in accordance with the shape of the substrate (display panel) 10 on which evaporation is to be performed. In this example, the wafer is cut into a rectangular shape, as indicated by dashed line in FIG. 7. If the mask is of a circular shape including unnecessary circular arc portions b in the periphery, there is a problem that, when the mask is mounted to an evaporation apparatus or the like for evaporation of an organic material, an mounting area must be increased and a large evaporation apparatus is required. Therefore, the circular arc portions b, which are not essential from a viewpoint of masking regions of the substrate 10 except necessary portions, are removed.

According to the foregoing process steps, a deposition mask 100 is completed.

In this embodiment, the thick portion 140 is provided along the outer periphery of the Si substrate. However, to thereby further enhance the rigidity of the mask the thick portion 140 may also be formed between the openings 110 in the region M.

As described above, with the configuration of the present embodiment, a highly accurate deposition mask can be formed using a photolithography technique. In particular, using the photolithography technique, a mask which is accurate in size, position, and dimension between the openings can be obtained. Further, since the mask is composed of a silicon substrate, the rigidity of the mask is improved compared to a metal mask having similar thickness. Accordingly, when evaporation is performed using this deposition mask, it is possible to prevent an organic material for forming an emissive layer of an organic EL element from being incorrectly evaporated on an anode of a display pixel for a wrong color which is adjacent to the target color display pixel. Thus, an organic EL display apparatus capable of clearly displaying desired colors without color mixture can be provided.

Further, even when an organic material is adhered to the deposition mask after repeated use, the organic material can be easily removed using a solvent. Since a mask composed of silicon is not easily attacked by such a solution for solving an organic material, the mask can be reused a plurality of times, leading to saving the cost. Also, since the mask has high rigidity due to the thick portion serving as an outer frame, it will not be broken easily when an organic material adhered to the mask is removed, and can be repeatedly used, thereby reducing the cost.

In particular, the workability of the mask is very high due to use of Si, as described above, and therefore the deposition openings as well as the opening forming region M (mask forming region M) can be formed easily and accurately.

Second Embodiment

A second preferred embodiment of the present invention will next be described.

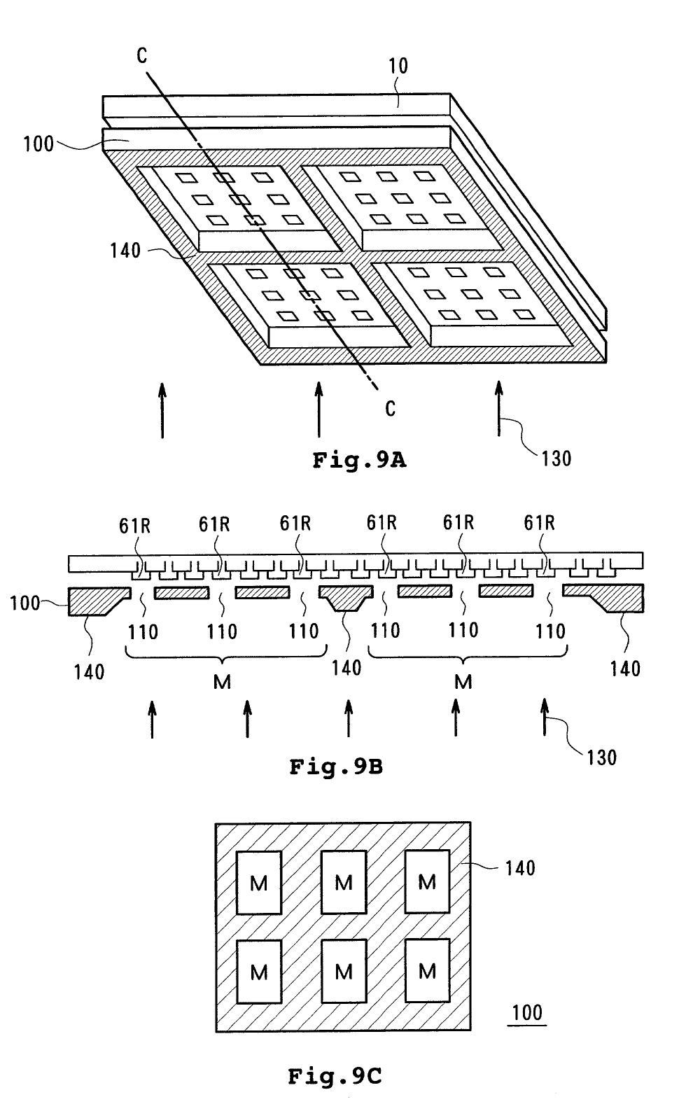

FIG. 9A shows, in a perspective view, a state where an organic material is to be evaporated onto a glass substrate using a deposition mask according to the second embodiment of the present invention. FIG. 9B is a cross sectional view taken along line C-C of FIG. 9A.

The deposition mask according to the second embodiment shown in FIGS. 9A and 9B differs from that in the first embodiment in that it is a large deposition mask used when performing evaporation onto a large size glass substrate, and in that such a large mask is reinforced so as to improve the rigidity. Specifically, when a plurality of opening forming regions M are provided in a single mask substrate, a thick portion 140 is formed at each gap between adjoining regions M, in addition to along the outer frame portion of the mask 100. In the example shown in FIGS. 9A and 9B, four of the regions M are provided in the mask 100, and the thick portion 140 is formed along the rectangular frame portion and in a cross-shaped pattern inside the frame. Further unlike the first embodiment, the deposition mask of the second embodiment is composed of polycrystalline silicon.

The polycrystalline Si substrate 100 used may be, for example, of a rectangular shape of 400 mm×400 mm, as indicated by dashed line a in FIG. 7, when the peripheral region is removed. The original shape of the substrate 100 is not limited to a circular shape as indicated, and may originally be of a rectangular shape of minimum size.

In this embodiment, as shown in FIG. 9A the thick portion 140 is formed in the center part of the mask 100, in addition to along the periphery (frame portion) of the mask 100. In other words, the thick portion 140 is provided along the entire surroundings of each region M. Thus, the deposition mask composed of Si (p-Si) can be reinforced due to the thick portion 140 additionally formed in the center part thereof, and therefore even a mask of large size will not be easily damaged.

Referring to FIG. 9B, the mask 100 is disposed such that the deposition openings 110 are located at positions corresponding to the anodes 61R of the display pixels for red color of the display pixels of R, G, B colors. The thick portion 140 formed in the center part of the mask 100 may have a width which is smaller than a gap between one anode 61R and an adjacent anode 61R.

A method of forming a mask according to this embodiment differs from the method described above for the first embodiment in that, rather than etching the opening forming region M using KOH as an etchant, the region M of the Si substrate is preformed to a significant degree using a grinder or the like, and the region M is completed by performing dry etching is then performed using an etching gas of SF₆.

It has been described that the thick portion 140 is also formed between a plurality of opening forming regions M in a single deposition mask 100. When a plurality of display panel regions are simultaneously formed in a single large substrate (a mother substrate) 10, namely in a simultaneous multi-panel forming method, the plurality of the regions M formed in one mask 100 respectively correspond to the display panel regions. Because the gap between the display panel regions is usually larger than the gap between pixels for the same color within one panel, the thick portion 140 can be easily formed as a sufficiently wide portion at a region corresponding to the above-mentioned gap between panel regions. In addition, such a wide thick portion 140 improves the reinforcing effect. It is preferable that the deposition mask 100 as shown in FIGS. 9A and 9B is used also when a single display panel is formed in a single large substrate 10. In such a case, the thick portion 140 formed in the center part of a single mask 100 is located between desired pixels in the center of the display panel. In this case, each region partitioned by this thick portion 140 corresponds to each of the region M shown in FIG. 9B.

Further, the pattern of the thick portion 140 formed in the deposition mask 100 is not limited to that shown in FIGS. 9A and 9B. For example, as shown in FIG. 9C, the thick portion 140 may be formed along the outer frame (outer periphery) of the mask 100 and also in a grid pattern within a region enclosed by this frame. The thick portion 140 may also be formed in another pattern, such as a mesh pattern.

Various patterns can be adopted for the thick portion 140 according to the size and rigidity of the large deposition mask 100 and the layout, size, and pixel pitch of a display panel to be formed using this mask 100.

In the foregoing embodiments, a deposition mask used for evaporating an organic material of red color onto a display pixel which emits red light among display pixels displaying R, G, and B colors was described. However, the mask is not limited to that for displaying red color, and a mask used for any other color can be formed in a similar manner by providing a deposition opening at a position corresponding to the anode of the display pixel displaying that color. Further, rather than manufacturing and using separate masks for different colors, it is also possible to use a single mask to perform evaporation of organic materials emitting all the R, G, or B colors, by shifting the mask in one direction so as to displace the openings correspondingly.

Further, although the foregoing embodiments have described a stripe pixel arrangement where the display pixels are arranged such that the pixels displaying the same color are aligned in the column direction to form a stripe pattern, the mask of the present invention is not limited to application to such pixel arrangement, and is also applicable to a so-called delta arrangement, or to a case where the display pixels for the same color are disposed diagonally from upper left to lower right. In these cases, the deposition openings of the mask are formed at positions corresponding to anodes of the display pixels for the same color.

As described above, the accuracy of a mask can be improved even for the deposition mask used in depositing a material to a large display device. Also, the rigidity of the mask is further increased by providing the thick portion in the center part of the mask as well.

Although only several openings of the deposition mask are shown for convenience of explanation in the foregoing embodiments, the number of mask openings actually corresponds to the number of pixels in each display apparatus, such as 852×222.

Further, when a polycrystalline silicon substrate is used to form a large deposition mask 100 as described above, a large substrate can be manufactured at a lower cost than when single crystal silicon is used and therefore an increase in a manufacturing cost resulting from increase in a mask size can be minimized.

While preferred embodiments of the present invention have been described using specific terms, such description is for illustrative purposes only, and it is to be understood that changes and variations may be made without departing from the spirit or scope of the appended claims.

What is claimed is:

1. A deposition mask for placing between a depositing material and a medium on which deposition is performed, including a pattern for allowing said depositing material to be selectively attached to a desired position on said medium, wherein
said mask is composed of a semiconductor substrate.

2. A deposition mask as defined in claim 1, wherein
said semiconductor substrate is composed of silicon.

3. A deposition mask for placing between a depositing material and a medium on which deposition is performed, comprising:
a semiconductor substrate including an opening forming region having a reduced thickness provided with at least one opening for allowing said depositing material to be selectively attached to a desired position on said medium, and a thick portion formed in at least one portion of an outer periphery region of said mask.

4. A deposition mask as defined in claim 3, wherein
said semiconductor substrate is composed of silicon.

5. A deposition mask as defined in claim 3, wherein
said semiconductor substrate is composed of single crystalline or polycrystalline silicon.

6. A method for manufacturing a deposition mask, wherein
said deposition mask for placing between a depositing material and a medium on which deposition is performed comprises a semiconductor substrate including an opening forming region having a reduced thickness provided with at least one opening for allowing said depositing material to be selectively attached to a desired position on said medium, and a thick portion formed in at least one portion of a mask outer periphery region of said semiconductor substrate,
said method comprising the steps of:
forming a first coating covering a region in which said thick portion of said semiconductor substrate is to be formed;
using said first coating as an etching mask to etch said semiconductor substrate so as to reduce thickness of said semiconductor substrate and thereby form said opening forming region;
forming a second coating in areas other than a predetermined position within said opening forming region; and
using said second coating as an etching mask to etch said semiconductor substrate so as to form said at least one opening in said predetermined position.

7. A deposition mask as defined in claim 6, wherein
said semiconductor substrate is composed of silicon.

8. A deposition mask manufacturing method as defined in claim 6, wherein
said first coating is formed on a first side of said semiconductor substrate;
said opening forming region is formed by etching said first side of said semiconductor substrate to reduce thickness of said substrate;
said second coating is formed on a second side of said semiconductor substrate; and
said at least one opening is formed by etching from said second side until penetrating through said semiconductor substrate.

9. A method for manufacturing an electroluminescence display device composed by arranging a plurality of display pixels, each display pixel having an electroluminescence element including at least an emissive layer between first and second electrodes, said method comprising the steps of:
arranging a deposition mask on a medium having said first electrode formed thereon; and
attaching an emissive material from an emissive material source via an opening in said deposition mask to a corresponding display pixel region of said medium, thereby forming an emissive layer for each pixel; wherein
said deposition mask for placing between a depositing material and said medium on which deposition is performed comprises a semiconductor substrate including an opening forming region having a reduced thickness provided with at least one opening for allowing said depositing material to be selectively attached to a desired position on said medium, and a thick portion formed in at least one portion of a mask outer periphery region of said semiconductor substrate; and
said deposition mask is obtained through the steps of:
forming a first coating covering a region in which said thick portion of said semiconductor substrate is to be formed;
using said first coating as an etching mask to etch said semiconductor substrate so as to reduce thickness of said semiconductor substrate and thereby form said opening forming region;
forming a second coating in areas other than a predetermined position within said opening forming region; and
using said second coating as an etching mask to etch said semiconductor substrate so as to form said at least one opening in said predetermined position.

10. A method for manufacturing an electroluminescence display device as defined in claim 9, wherein
each of said elements includes between said first and second electrodes at least an emissive layer containing an organic material; and
said organic material supplied from said emissive material source is attached via said opening of said deposition mask to a corresponding pixel.

11. A method for manufacturing an electroluminescence display device as defined in claim 9, wherein
each of said elements is composed by including between said first and second electrodes at least an emissive layer containing an organic material corresponding to an emitted color; and
said deposition mask having said opening formed only in a region corresponding to a pixel for a predetermined color is used to attach said organic material supplied from said emissive material source to a corresponding pixel region.

12. An electroluminescence display device formed using the manufacturing method defined in claim 9.

13. A color organic electroluminescence display device formed using the manufacturing method defined in claim 9.
